(19) United States
(12) Patent Application Publication
(10) Pub. No.: US 2012/0305878 A1
(43) Pub. Date: Dec. 6, 2012

(54) RESISTIVE SWITCHING MEMORY DEVICE

(75) Inventors: Michael Miller, San Jose, CA (US); Prashant Phatak, San Jose, CA (US); Tony Chiang, Campbell, CA (US)

(73) Assignee: INTERMOLECULAR, INC., San Jose, CA (US)

(21) Appl. No.: 13/149,528

(22) Filed: May 31, 2011

(51) Int. Cl. H01L 45/00

(52) U.S. Cl. 257/4; 438/382; 257/E45.003

(57) ABSTRACT

A nonvolatile memory element may include, but is not limited to: a first electrode; a second electrode; and a resistive switching material disposed between the first electrode and the second electrode, wherein at least one of the first electrode or the second electrode includes at least one of a metal cation or metalloid cation having a valence state, oxidation state or oxidation number and wherein the resistive switching material includes at least one of a metal cation or a metalloid cation having the same valence state oxidation state or oxidation number as the at least one of a metal cation or metalloid cation of the at least one of the first electrode or the second electrode.

### TECHNICAL FIELD

The present invention relates to the field of non-volatile memory elements and, more particularly, resistive switching memory elements.

### BACKGROUND

Nonvolatile memory elements may be used in systems in which persistent storage may be required. For example, digital cameras use nonvolatile memory cards to store images and digital music players use nonvolatile memory to store audio data. Nonvolatile memory may be also used to persistently store data in computer environments.

Nonvolatile memory may be often formed using electrically-erasable programmable read only memory (EPROM) technology. This type of nonvolatile memory contains floating gate transistors that may be selectively programmed or erased by application of suitable voltages to their terminals.

As fabrication techniques improve, it is becoming possible to fabricate nonvolatile memory elements with increasingly small dimensions. However, as device dimensions shrink, scaling issues pose challenges for traditional nonvolatile memory technology. This has led to the investigation of alternative nonvolatile memory technologies, including resistive switching nonvolatile memory.

### BRIEF DESCRIPTION OF THE DRAWINGS

FIG. 1 shows an illustration of electron energy levels.

FIG. 2 shows an exemplary array of nonvolatile memory elements.

FIG. 3 shows a graph representing bistable behavior of a resistive switching memory element.

FIG. 4 shows a cross-sectional view of an exemplary resistive switching memory element.

FIG. 5 shows a table including various electrode/resistive switching material combinations.

### DETAILED DESCRIPTION

Resistive switching nonvolatile memory is formed using memory elements that have two or more stable states (i.e. is bistable) with different resistances. A bistable memory element can be placed in a high resistance state or a low resistance state by application of suitable voltages or currents. Voltage pulses are typically used to switch the memory element from one resistance state to the other. Non-destructive read operations can be performed to ascertain the value of a data bit that is stored in a memory cell.

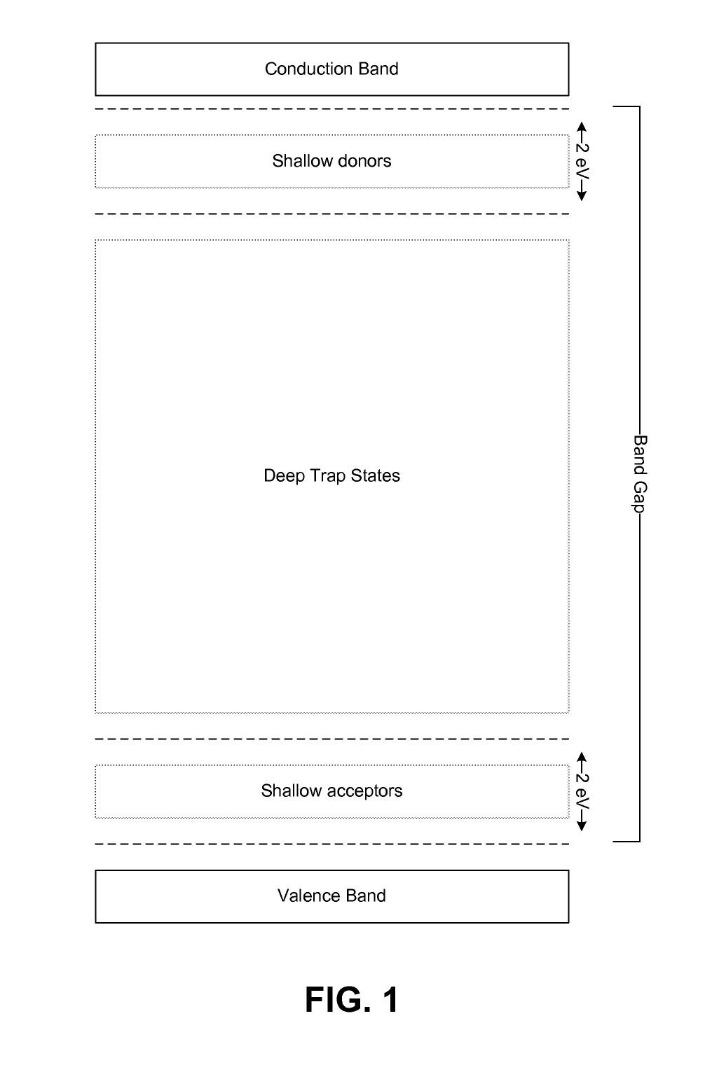

The source of the bistable resistive switching characteristics of a resistive switching material may be the presence of atoms that provide deep electron trap states within the resistive switching material. As shown in FIG. 1, an energy difference (i.e. a band gap) may exist between the top of a valence band and the bottom of a conduction band. This energy difference is the energy required to free an outer shell electron from its orbit about the nucleus to become a mobile charge carrier, able to move freely within a material. As shown in FIG. 1, electron states which are within a threshold energy level (e.g. approximately 2 eV of either the valence band or the conduction band may be characterized as shallow trap states (i.e. shallow acceptor trap states and shallow donor trap states) where electrons may move into either the valence band or the conduction band more readily than electrons within deep trap states which are more than the threshold energy level (e.g. approximately 2 eV) away from either the valence band or the conduction band. The presence of various impurities and/or defects within the material may serve to increase the availability of such deep trap states which more readily retain electrons within the band gap energies thereby enhancing the resistive switching characteristics of the resistive switching material.

For example, the presence of metal and/or metalloid atoms (e.g. including Group IIIA, IIIB, IVA, IVB, VA and/or VB atoms) may provide such deep electron trap states. In order to optimize the performance of a resistive switching memory element, it may be desirable to provide a resistive switching memory element including a resistive switching material configured to maximize the number of deep electron trap states within the resistive switching material.

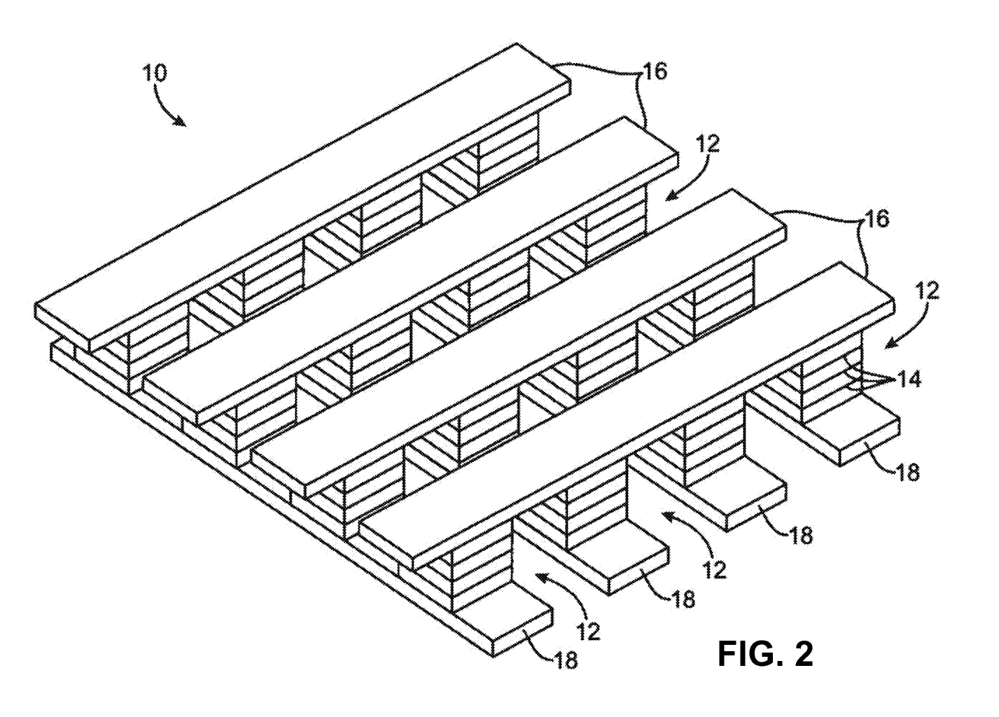

An illustrative memory array 10 of nonvolatile memory elements 12 is shown in FIG. 2. The array 10 may be part of a memory device or other integrated circuit. Read and write circuitry may be connected to memory elements 12 using conductors 16 and conductors 18. Conductors such as conductors 16 and conductors 18 may be generally orthogonal. Such conductors may be sometimes referred to as word lines and bit lines and may be used to read data from the memory elements 12 in the array 10 and to write data into the memory elements 12 in array 10. Individual memory elements 12 or groups of memory elements 12 may be addressed using appropriate sets of conductors 16 and 18. The memory elements 12 may be formed from one or more layers of materials, as indicated schematically by lines 14 in FIG. 2. In addition, memory arrays such as array 10 may be stacked in a vertical fashion to provide multilayer array 10 structures including three-dimensional distributions of memory elements 12.

During a write operation, the state of the memory element may be changed by application of suitable write signals to an appropriate set of conductors 16 and 18.

The voltage that may be used to change a memory element 12 from its high resistance state to its low resistance state may be generally referred to as the set voltage (Vₛₑₜ) of the memory element 12. When a voltage equal to Vₛₑₜ is applied to the memory element 12, the memory element 12 may transition from its high resistance state to its low resistance state.

The voltage that may be used to change a memory element 12 back to its high resistance state from its low resistance state may be generally referred to as its reset voltage (Vᵣₑₛₑₜ). When a memory element 12 is in its low resistance state and a voltage equal to Vᵣₑₛₑₜ is applied, the memory element 12 may transition to its high resistance state. The reset voltage may have the same polarity as the set voltage or may have an opposite polarity (i.e., the reset voltage may be negative while the set voltage may be positive).

Once the memory element 12 is in use in a device, a read voltage V_{read} read may be applied to the memory element to detect its resistance state (high or low). The amount of current that flows through the memory element 12 at V_{read} when the memory element 12 is in its high resistance state may be generally referred to as its “off current” (i.e., I_{off}).

The amount of current that flows through the memory element 12 at V_{read} read when the memory element 12 is in its low resistance state may be generally referred to as its “on current” (i.e., Iₒₙ). It may be desirable for the ratio of Iₒₙ to I_{off} to be as large as possible, to facilitate the detection of state changes in the memory element 12 during read operations. For example, it may be desirable for the ratio of Iₒₙ to I_{off} to be greater than or equal to 5, 50, or 500.

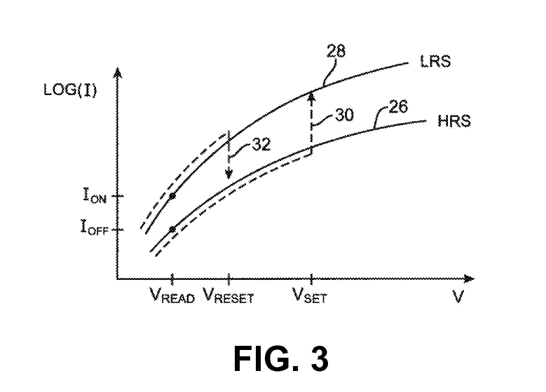

A current (I) versus voltage (V) plot for an illustrative nonvolatile memory element 12 is shown in FIG. 3. Initially, memory element 12 may be in a high resistance state (HRS) (e.g., storing a logic one). In this state, the current versus voltage characteristic of memory element 12 may be represented by solid line HRS 26.

The memory element 12 may be placed using read and write circuitry to apply a voltage Vₛₑₜ across conductors 16 and 18 of memory element 12. Applying Vₛₑₜ to memory element 12 causes memory element 12 to enter its low resistance state, as indicated by dotted line 30 of FIG. 3. In this region, the structure of memory element 12 is changed (e.g., through the formation of percolative current paths through the resistive switching material of memory element 12 or other suitable mechanisms), so that, following removal of the voltage Vₛₑₜ, memory element 12 may be characterized by low resistance state (LRS) 28 (e.g., storing a logic zero). The low resistance state of memory element 12 may be sensed using the read and write circuitry. When a read voltage V_{read} is applied across conductors 16 and 18 of memory element 12, the read and write circuitry may sense the relatively high current value Iₒₙ that lows through memory element 12, indicating that memory element 12 may be in its low resistance state.

The memory element 12 may be placed in its high resistance state by applying a voltage Vᵣₑₛₑₜ to memory element 12. When the read and write circuitry applies Vᵣₑₛₑₜ to memory element 12, memory element 12 enters its high resistance state (HRS), as indicated by dotted line 32. When the voltage Vᵣₑₛₑₜ is removed from memory element 12, memory element 12 will be characterized by high resistance state HRS 26. The high resistance state of memory element 12 may be sensed by read and write circuitry associated with an array 10 of memory element 12. For example, read and write circuitry may apply a read voltage V_{read} to a memory element 12 and may sense the relatively low current I_{off} that flows through memory element 12, indicating that memory element 12 may be in its high resistance state

When Vᵣₑₛₑₜ is positive, Vₛₑₜ may be either positive or negative. A situation in which Vᵣₑₛₑₜ may be positive may be illustrated in the example of FIG. 3. In one embodiment, Vᵣₑₛₑₜ may be positive at an anode of the memory element 12, while Vₛₑₜ may be positive (for unipolar operation) or negative (for bipolar operation). Voltage pulses for Vₛₑₜ and Vᵣₑₛₑₜ may have durations of from 2 ns to 2 ms and from 2 ns to 500 ns, respectively.

The bistable resistance of resistive switching memory element 12 described above makes memory element 12 suitable for storing digital data. Because no changes take place in the stored data in the absence of application of the voltages Vₛₑₜ and Vᵣₑₛₑₜ, memory formed from elements such as memory element 12 may be nonvolatile.

Data values may be assigned to the high and low resistance values. For example, the memory element 12 may be said to contain a logical one (i.e., a “1” bit) when it exhibits the high resistance at V_{read}. If, on the other hand, the memory element 12 may be said to contain a logical zero (i.e., a “0” bit) if the memory element 12 exhibits the low resistance value. These value assignments may be reversed, if desired (i.e., the low resistance state may be said to correspond to a “1” and the high resistance state may be said to correspond to a “0”).

Any suitable read and write circuitry and array 10 layout scheme may be used to construct a nonvolatile memory device from resistive switching memory elements such as memory element 12. For example, horizontal and/or vertical conductors 16 and 18 may be connected directly to the terminals of resistive switching memory elements 12.

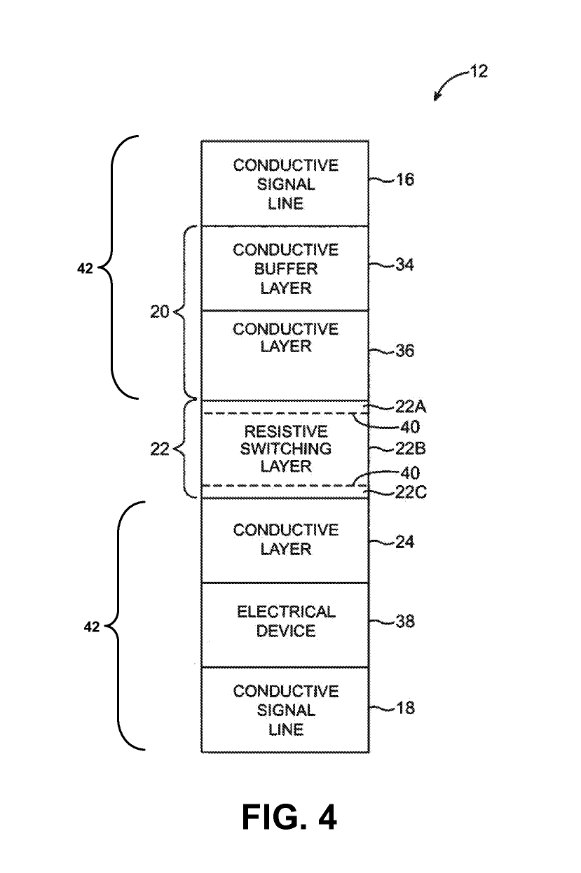

A cross-sectional view of an illustrative embodiment of a resistive switching memory element is shown in FIG. 4. In the example of FIG. 4, memory element 12 may include a resistive switching material 22. As indicated schematically by lines 40, resistive switching material 22 may include one or more sublayers of resistive switching material (e.g., sublayers such as a cap layer 22A, a main layer 22B, and base layer 22C).

As shown in FIG. 4, one or more layers of conductors may optionally be connected in series with resistive switching material 22 in memory element 12. For example, resistive switching material 22 may be electrically connected between an upper conductive layer such as a portion of a conductor 16 and a lower conductive layer such as a portion of a conductor 18. Alternately, layers having various functions may also be included in memory element 12. For example, additional layers may be included in memory element 12 to modify the electrical properties of memory element 12, to promote adhesion, to form barrier layers, to form electrical devices, etc.

In an exemplary configuration, the resistive switching material 22 may be disposed in a position adjacent to a top electrode 20 (e.g. an electrode formed from a conductive buffer layer 34 and a conductive layer 36 or a single lower electrode 24).

Conductive layers such as electrodes 20 and 24 may be formed of a single layer of conductive material or may be formed of multiple conductive layers. The composition of the electrodes 20 and 24 in memory element 12 may affect resistive switching performance of the resistive switching material 22, as described below. Suitable materials for electrodes 20 and 24 may include, but are not limited to, metals, metalloids, metal oxides, metal nitrides, metal phosphides or metal sulfides.

If desired, one or both of the electrodes 20 and 24 may be formed from multiple sublayers. As an example, As an example, electrode 20 may be formed from conductive layer 36 and conductive buffer layer 34. Layers such as conductive buffer layer 34 and conductive layer 36 may be formed from multiple sublayers of material (e.g., to promote adhesion, etc.).

The conductive buffer layer 34 may serve as a buffer layer to stabilize the electrode 20. The conductive layer 36 may be prone to thermal decomposition when heat may be applied to memory element 12 (e.g., during fabrication or during operation). For example, the application of heat may produce compounds that could potentially diffuse through memory element 12 (e.g., upwards into conductor 16, which might be formed from a metal such as tungsten, aluminum, or copper). This could potentially lead to reliability problems for memory element 12. The conductive buffer layer 34 may prevent undesired thermal decomposition and migration of materials in conductive layer 36 and may thereby ensure that memory element 12 exhibits thermal stability and reliable operation. Similarly, conductive buffer layer 34 may also promote stability in memory element 12 by preventing the material of conductor 16 from migrating into conductive layer 36.

Any suitable material may be used for conductive buffer layer 34. For example, conductive buffer layer 34 may be formed from a metal nitride (e.g., a binary or ternary metal nitride), a metal oxide (e.g., a conductive metal oxide such as nickel oxide or ruthenium oxide), a metal silicon nitride, a metal carbide, or a metal carbide nitride.

Further, the memory element 12 may include an optional electrical component 38 that may be connected in series with resistive switching material 22. For example, the electrical component 38 may include a current steering element 38. A current steering element 38 may include, for example, diodes, p-i-n diodes, silicon diodes, silicon p-i-n diodes, transistors, etc.

The layers of material in memory element 12 may be deposited using any suitable fabrication technique (e.g., physical or chemical vapor deposition, electrochemical deposition, ion implantation, atomic layer deposition, sputtering etc.).

As presented above, the source of the bistable resistive switching characteristics of the resistive switching material 22 may be the presence of atoms that provide deep electron trap states within the resistive switching material 22. For example, metal and/or metalloid atoms (e.g. including Group IIIA, IIIB, IVA, IVB, VA and/or VB atoms) may provide such deep electron trap states. In order to optimize the performance of a memory element 12, it may be desirable to maximize the number of such deep electron trap states within the resistive switching material 22.

During memory access operations in a memory element 12 (as described above) various conductive paths, such as filamentary current paths or defect-based current paths may be formed through the resistive switching material 22 to provide for signal propagation through the resistive switching material 22. In both signal propagation mechanisms, electromigration of atoms of the electrodes 20 and 24 and/or conductors 16 and 18, (hereinafter, collectively, “electrodes 42”) may occur within the resistive switching material 22.

In order to increase the population of deep trap states within the resistive switching material 22, thereby enhancing the resistive switching properties of the resistive switching material 22, the compositions of the electrodes 42 and resistive switching material 22 may be selected such that the electrodes 42 include atoms that are themselves deep traps when present within a given resistive switching material 22. In such a configuration the population of deep electron trap states may be enhanced during the memory access operations as atoms of the electrodes 42 migrate into the resistive switching material 22.

It may be the case that certain metal atoms lead to less desirable shallow trap states. For example, electrodes 42 including metal and/or metalloid atoms that lead to shallow trap states may include those with a valence state, oxidation state and/or oxidation number one higher or one lower than the valence state, oxidation state and/or oxidation number of the metal in a metal oxide resistive switching material 22. Such metals may become donors or acceptors and form shallow trap states. Elements with valence states, oxidation states and/or oxidation numbers two more or two less may create both deep and shallow trap states.

However, electrodes 42 including metal and/or metalloid atoms that have the same valence state, oxidation state and/or oxidation number (collectively referred to herein as “isovalent”) with respect to the metal in the metal oxide of the resistive switching material 22 may lead to deep trap states.

Therefore, electrodes 42 including metal and/or metalloid atoms that are isovalent with respect to the metal and/or metalloid atoms in the resistive switching material 22 may be employed to enhance the number of deep trap states within the resistive switching material 22 under operating conditions. The deep trap states may improve switching stability and/or improve data retention. The traps may have energy levels greater than or approximately equal to 200 meV in one embodiment.

For example, the resistive switching material 22 may include one or more layers (e.g. cap layer 22A, main layer 22B and base layer 22C) including one or more metals and/or metalloids having an associated cation with a valence state, oxidation state and/or oxidation number of +3 (e.g. oxides, nitrides, phosphides, and/or sulfides of scandium, yttrium, lanthanum, boron, aluminum, gallium, indium, thallium, erbium, and/or holmium).

Accordingly, one or more of the electrodes 42 may include one or more metals and/or metalloids having an associated cation with a valence state, oxidation state and/or oxidation number of +3 (e.g. rhodium, chromium, aluminum, gallium, indium, thallium, holmium, scandium, yttrium, lanthanum, erbium, iron, and conductive nitrides and alloys thereof).

In one example, the resistive switching material 22 may include one or more of oxides, nitrides, phosphides, and/or sulfides of boron, aluminum, gallium, indium, thallium, and/or holmium while the electrodes 42 may include one or more of scandium, yttrium, lanthanum, and conductive oxides, nitrides, phosphides, sulfides and/or alloys thereof.

In another example, the resistive switching material 22 may include at least one of aluminum oxide, aluminum nitride, lanthanum oxide, lanthanum nitride, yttrium oxide, or yttrium nitride while the electrodes 42 may include one or more of scandium metal, yttrium metal and lanthanum metal.

The metal and/or metalloid of the resistive switching material 22 and the electrodes 42 may be the same or different. For example, the resistive switching material 22 may include yttrium oxide while the electrodes 42 may include conductive yttrium nitride. Alternately, the resistive switching material 22 may include yttrium oxide while the electrodes 42 may include lanthanum metal.

Further, the metal and/or metalloid of the cap layer 22A and the main layer 22B may be the same or different. For example, the cap layer 22A may include yttrium nitride or phosphide while the main layer 22B may include yttrium oxide. Alternately, the cap layer 22A may include scandium oxide while the main layer 22B may include aluminum oxide.

Alternately, the resistive switching material 22 may include one or more layers (e.g. cap layer 22A, main layer 22B and base layer 22C) including one or more metals and/or metalloids having an associated cation with a valence state, oxidation state and/or oxidation number of +4 (e.g. oxides, nitrides, phosphides, and/or sulfides of carbon, silicon, germanium, tin, lead, erbium, titanium, zirconium, hafnium, cerium).

Accordingly, one or more of the electrodes 42 may include one or more metals and/or metalloids having an associated cation with a valence state, oxidation state and/or oxidation number of +4 (e.g. platinum, ruthenium, iridium, osmium, titanium, zirconium, hafnium, cerium, carbon, silicon, germanium, tin, and lead, and nitrides, phosphides and alloys thereof).

In one example, the resistive switching material 22 may include one or more of oxides, nitrides, phosphides, and/or sulfides of carbon, silicon, germanium, tin, hafnium, and titanium while the electrodes 42 may include one or more of platinum, ruthenium, iridium, osmium, silicon, titanium, zirconium, hafnium, cerium, and conductive nitrides, phosphides and alloys thereof.

In another example, the resistive switching material 22 may include at least one of hafnium oxide, titanium oxide, zirconium oxide or cerium oxide while the electrodes 42 may include at least one of titanium nitride, n-type silicon or p-type silicon.

The metal and/or metalloid of the resistive switching material 22 and the electrodes 42 may be the same or different. For example, the resistive switching material 22 may include titanium oxide while the electrodes 42 may include titanium nitride. Alternately, the resistive switching material 22 may include hafnium oxide while the electrodes 42 may include titanium nitride.

Further, the metal and/or metalloid of the cap layer 22A and the main layer 22B may be the same or different. For example, the cap layer 22A may include dielectric hafnium nitride while the main layer 22B may include hafnium oxide. Alternately, the cap layer 22A may include titanium oxide while the main layer 22B may include hafnium oxide.

Alternately, the resistive switching material 22 may include one or more layers (e.g. cap layer 22A, main layer 22B and base layer 22C) including one or more metals and/or metalloids having an associated cation with a valence state, oxidation state and/or oxidation number of +5 (e.g. oxides, nitrides, phosphides and/or sulfides of antimony, bismuth, vanadium, niobium, tantalum, and arsenic).

Accordingly, one or more of the electrodes 42 may include one or more metals and/or metalloids having an associated cation with a valence state, oxidation state and/or oxidation number of +5 (e.g. vanadium, niobium, tantalum, antimony and/or bismuth, and conductive nitrides, phosphides and alloys thereof).

In one example, the resistive switching material 22 may include one or more of oxides, nitrides, phosphides and sulfides of Niobium and Tantalum, while the electrodes 42 may include one or more of antimony, vanadium, niobium, tantalum, and conductive nitrides and alloys thereof.

In another example, the resistive switching material 22 may include niobium oxide while the electrodes 42 may include at least one of vanadium metal, vanadium nitride, tantalum metal, or tantalum nitride.

The metal and/or metalloid of the resistive switching material 22 and the electrodes 42 may be the same or different. For example, the resistive switching material 22 may include niobium oxide while the electrodes 42 may include niobium nitride. Alternately, the resistive switching material 22 may include niobium oxide while the electrodes 42 may include tantalum metal.

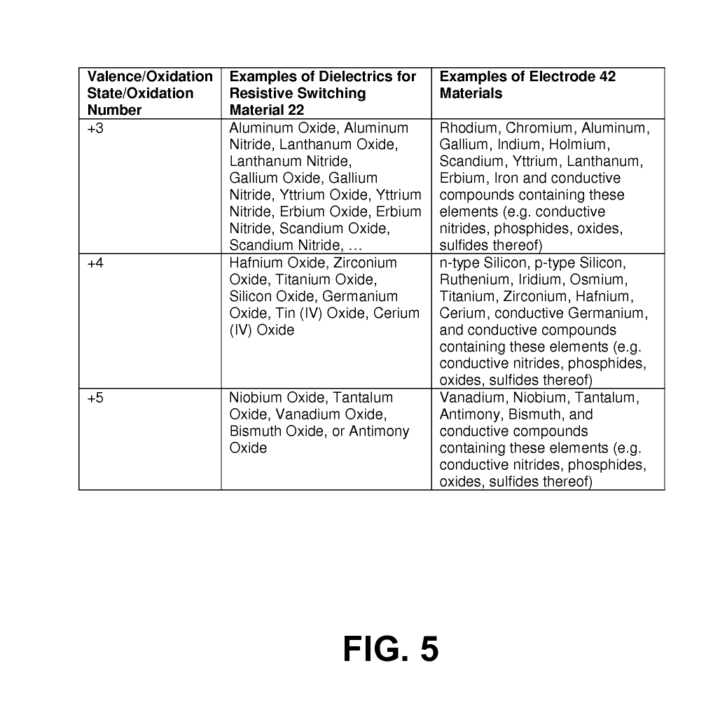

Referring to FIG. 5, various candidate materials for the resistive switching material 22 and the electrodes 42 are shown.

If desired, thermal stability and resistive switching performance may be promoted by using multiple sublayers of material in resistive switching layer 22. Three such sublayers are shown as layers 22A, 22B, and 22C in the example of FIG. 4. The metal and/or metalloid of the cap layer 22A and the main layer 22B may be the same or different. For example, the cap layer 22A may include dielectric niobium nitride or phosphide while the main layer 22B may include niobium oxide. Alternately, the cap layer 22A may include dielectric niobium nitride while the main layer 22B may include vanadium oxide.

Optionally, the materials of resistive switching material 22 may be doped with suitable dopants. For example, resistive switching material 22 may include one or more layers of aluminum oxide interspersed with one or more layers of titanium oxide. In this type of scenario, it may be desirable to incorporate aluminum (e.g., elemental aluminum or aluminum oxide) into the titanium oxide as a dopant to help improve the thermal stability of the titanium oxide and/or to improve resistive switching performance. As another example, one or more of the layers in resistive switching material 22 may be doped with hafnium. The use of aluminum and hafnium as dopants is, however, merely illustrative. Other dopant materials may be used to dope resistive switching material 22 if desired. Any suitable concentration of dopant may be used in resistive switching material 22.

The inclusion of a dopant in resistive switching material 22 may enhance the thermal stability of resistive switching material 22 (e.g., by raising its melting point or, when resistive switching material 22 includes more than one layer, by raising the melting point of one or more of the sublayers in resistive switching material 22). For example, the inclusion of a dopant such as aluminum in a resistive switching material 22 formed from titanium oxide may help to raise the melting point of the resulting resistive switching material 22. A raised melting point may be indicative of improved thermal stability. Enhancing the thermal stability of resistive switching material 22 may be advantageous, particularly when resistive switching material 22 and the other portions of memory element 12 may be formed on an integrated circuit in which other electronic structures may be in the process of being fabricated. When thermal stability for resistive switching material 22 may be enhanced, resistive switching material 22 may be less likely to react with adjacent materials and/or exhibit a change in structure (e.g., due to changes in crystallinity).

What is claimed is:

1. A nonvolatile memory element comprising:
a first electrode;
a second electrode; and
a resistive switching material placed between the first electrode and the second electrode,
wherein at least one of the first electrode or the second electrode includes at least one of a metal cation or a metalloid cation having at least one of a valence state, an oxidation state or an oxidation number, and
wherein the resistive switching material includes at least one of a metal cation or a metalloid cation having at least one of a valence state, an oxidation state or an oxidation number that is the same as the at least one of the valence state, the oxidation state or the oxidation number of the at least one of a metal cation or a metalloid cation of the at least one of the first electrode or the second electrode.

2. The nonvolatile memory element of claim 1, wherein the at least one of the valence state, the oxidation state or the oxidation number of the at least one of a metal cation or a metalloid cation of the at least one of the first electrode or the second electrode and the at least one of the valence state, the oxidation state or the oxidation number of the at least one of a metal cation or a metalloid cation of the resistive switching material is +3.

3. The nonvolatile memory element of claim 2,
wherein the at least one of a metal cation or a metalloid cation of the at least one of the first electrode or the second electrode is selected from at least one of rhodium, chromium, scandium, yttrium, lanthanum, aluminum, gallium, indium, thallium, erbium, iron, or holmium, and
wherein the at least one of a metal cation or a metalloid cation of the resistive switching material is selected from at least one of scandium, yttrium, lanthanum, boron, aluminum, gallium, indium, thallium, erbium, iron, or holmium.

4. The nonvolatile memory element of claim 3,
wherein the at least one of a metal cation or a metalloid cation of the at least one of the first electrode or second electrode is selected from at least one of rhodium, chromium, scandium, yttrium or lanthanum, and
wherein the at least one of a metal cation or a metalloid cation of the resistive switching material is selected from at least one of boron, aluminum, gallium, indium, lanthanum, or holmium.

5. The nonvolatile memory element of claim 3,
wherein at least one of the first electrode or the second electrode includes at least one of rhodium metal, chromium metal, scandium metal, yttrium metal or lanthanum metal, and
wherein the resistive switching material includes at least one of aluminum oxide, aluminum nitride, lanthanum oxide, lanthanum nitride, yttrium oxide, yttrium nitride, gallium oxide or gallium nitride.

6. The nonvolatile memory element of claim 3,
wherein the resistive switching material includes at least one anion selected from: at least one of an oxide, a nitride, a phosphide or a sulfide.

7. The nonvolatile memory element of claim 3, further comprising:
a cap layer disposed between the resistive switching material and at least one of the first electrode or the second electrode, the cap layer including:
at least one of a metal cation or a metalloid cation selected from at least one of scandium, yttrium, lanthanum, boron, aluminum, gallium, indium, thallium, or holmium.

8. The nonvolatile memory element of claim 1, wherein the at least one of the valence state, the oxidation state or the oxidation number of the at least one of a metal cation or a metalloid cation of the at least one of the first electrode or the second electrode and the at least one of the valence state, the oxidation state or the oxidation number of the at least one of a metal cation or a metalloid cation of the resistive switching material is +4.

9. The nonvolatile memory element of claim 8,
wherein the at least one of a metal cation or a metalloid cation of the at least one of the first electrode or the second electrode is selected from at least one of platinum, ruthenium, iridium, osmium, titanium, zirconium, hafnium, cerium, carbon, silicon, germanium, tin, or lead,
wherein the at least one of a metal cation or a metalloid cation of the resistive switching material is selected from at least one of zirconium, hafnium, cerium, carbon, silicon, germanium, tin, or lead.

10. The nonvolatile memory element of claim 8,
wherein the at least one of a metal cation or a metalloid cation of the at least one of the first electrode or the second electrode is selected from at least one of ruthenium, iridium, osmium, titanium, zirconium, hafnium, cerium, carbon, silicon, germanium, tin or lead, and
wherein the at least one of a metal cation or a metalloid cation of the resistive switching material is selected from at least one of titanium, zirconium, hafnium, cerium, carbon, silicon, germanium, tin, or lead.

11. The nonvolatile memory element of claim 10,
wherein the at least one of a metal cation or a metalloid cation of the at least one of the first electrode or the second electrode includes at least one of ruthenium, iridium, osmium, carbon, silicon, germanium, tin or lead, and
wherein the at least one of a metal cation or a metalloid cation of the resistive switching material includes at least one of titanium, zirconium, hafnium or cerium.

12. The nonvolatile memory element of claim 10,
wherein at least one of the first electrode or the second electrode includes at least one of titanium nitride, n-type silicon or p-type silicon, and
wherein the resistive switching material includes at least one of hafnium oxide, titanium oxide, zirconium oxide or cerium oxide.

13. The nonvolatile memory element of claim 10,
wherein the resistive switching material includes at least one anion selected from: at least one of an oxide, a nitride, a phosphide or a sulfide.

14. The nonvolatile memory element of claim 8, further comprising:
a cap layer disposed between the resistive switching material and at least one of the first electrode or the second electrode.

15. The nonvolatile memory element of claim 14:
wherein at least one of the first electrode or the second electrode includes at least one of titanium nitride, n-type silicon or p-type silicon,
wherein the resistive switching material includes at least one of hafnium oxide, zirconium oxide or cerium oxide, and
wherein the cap layer includes titanium oxide.

16. The nonvolatile memory element of claim 14:
wherein the cap layer includes one or more materials having at least on of a valence state, oxidation state or oxidation number different than at least one of the resistive switching material, the first electrode or the second electrode.

17. The nonvolatile memory element of claim 1, wherein the at least one of the valence state, the oxidation state or the oxidation number of the at least one of a metal cation or a metalloid cation of the at least one of the first electrode or the second electrode and the at least one of the valence state, the oxidation state or the oxidation number of the at least one of a metal cation or a metalloid cation of the resistive switching material is +5.

18. The nonvolatile memory element of claim 17,
wherein the at least one of a metal cation or a metalloid cation of the at least one of the first electrode or the second electrode includes at least one of vanadium, niobium, tantalum, antimony, arsenic, or bismuth, and
wherein the at least one of a metal cation or a metalloid cation of the resistive switching material includes at least one of vanadium, niobium, tantalum, antimony or bismuth.

19. The nonvolatile memory element of claim 18,
wherein the resistive switching material includes at least one anion selected from: an oxide, a nitride, a phosphide or a sulfide.

20. The nonvolatile memory element of claim 18, further comprising:
a cap layer disposed between the resistive switching material and at least one of the first electrode or the second electrode, the cap layer including at least one of a metal cation or a metalloid cation selected from at least one of vanadium, niobium, tantalum, antimony or bismuth, the at least one of a metal cation or a metalloid cation of the cap layer being different than the at least one of a metal cation or a metalloid cation of the resistive switching layer.

21. A method of forming a nonvolatile memory element comprising:
disposing a resistive switching material between a first electrode and a second electrode,
wherein at least one of the first electrode or the second electrode includes at least one of a metal cation or a metalloid cation having at least one of a valence state, an oxidation state or an oxidation number, and
wherein the resistive switching material includes at least one of a metal cation or a metalloid cation having at least one of a valence state, an oxidation state or an oxidation number that is the same as the at least one of the valence state, the oxidation state or the oxidation number of the at least one of a metal cation or a metalloid cation of the at least one of the first electrode or the second electrode.

22. The method of forming a nonvolatile memory element of claim 21, wherein the at least one of the valence state, the oxidation state or the oxidation number of the at least one of a metal cation or a metalloid cation of the at least one of the first electrode or the second electrode and the at least one of the valence state, the oxidation state or the oxidation number of the at least one of a metal cation or a metalloid cation of the resistive switching material is selected from +3, +4 or +5.
